(19) United States
(12) Patent Application Publication
(10) Pub. No.: US 2006/0068601 A1
(43) Pub. Date: Mar. 30, 2006

(54) Wafer for compound semiconductor devices, and method of fabrication

(76) Inventors: Jeong-Sik Lee, Niiza-shi (JP); Tomoya Sugahara, Niiza-shi (JP)

Correspondence Address: WOODCOCK WASHBURN LLP, ONE LIBERTY PLACE, 46TH FLOOR, 1650 MARKET STREET, PHILADELPHIA, PA, 19103, US

(21) Appl. No.: 11/233,672

(22) Filed: Sep. 23, 2005

(30) Foreign Application Priority Data
Sep. 29, 2004 (JP) 2004-283567

(51) Int. Cl. H01L 21/31

(52) U.S. Cl. 438/761

(57) ABSTRACT

A wafer for fabrication of nitride semiconductor devices such as LEDs, HEMTs and FETs. The matrices of desired semiconductor devices are grown on a silicon substrate via a buffer region designed to keep the wafer from warping. The buffer region is in the form of alternations of multi-sublayered first buffer layers and non-sublayered, open-worked second buffer layers.

### CROSS REFERENCE TO RELATED APPLICATIONS

This application claims priority to Japanese Patent Application No. 2004-283567, filed Sep. 29, 2004.

### BACKGROUND OF THE INVENTION

This invention relates to semiconductor wafers, and more specifically to those particularly well suited for use in making such compound semiconductor devices as light-emitting diodes (LEDs), high-electron-mobility transistors (HEMTs), and field-effect transistors (FETs). The invention also concerns a method of making such semiconductor wafers.

The wafer for the fabrication of nitride-based compound semiconductor devices, for example, consists of a sapphire, silicon carbide, or silicon substrate and, grown thereon by epitaxy, a lamination of semiconductor layers constituting the matrices of the desired devices. Japanese Unexamined Patent Publication No. 2003-59948 suggests use of a silicon substrate as a less expensive substitute for a sapphire or silicon carbide one. One of the problems encountered in use of a silicon substrate was a difference in linear expansion coefficient between the silicon substrate and the main semiconductor region of nitride-based chemical compounds grown thereon to provide the matrices of desired semiconductor devices to be made. Stressed as a result of this difference, the main semiconductor region was highly susceptible to such defects as cracks and dislocations.

In order to overcome this weakness of the silicon substrate, the noted Japanese patent application teaches a so-called buffer region of multilayered design through which the main semiconductor region is grown on the substrate. Itself incorporating dislocations, the multilayered buffer region mitigates stresses and so saves the overlying main semiconductor region from cracks and dislocations.

This solution has proved not totally satisfactory, however, as semiconductor makers today develop and use larger and larger wafers for reduction of the manufacturing costs. The silicon wafers having the main semiconductor region grown thereon via the buffer region become increasingly more susceptible to warpage as they become larger. Take, for instance, the silicon substrate wafers of two-inch diameter and those of five-inch diameter. The two-inch wafers have an average warpage of fifty micrometers whereas the five-inch wafers have that of one hundred micrometers. It has also proved that wafers warp more with an increase in the thickness of the semiconductor region grown thereon, despite the fact that thicker semiconductor regions enable the resulting devices to withstand higher voltages. Out-of-shape wafers must be avoided as far as possible since they impede such indispensable manufacturing processes of semiconductor devices as photolithography.

Another requirement that has been left not totally met in conjunction with silicon substrate wafers is the improvement of the crystallinity of the main semiconductor region. The crystallinity of the main semiconductor region depends much upon the buffer region. Difficulties have been experienced in growing relatively thick main semiconductor regions of good crystallinity on the buffer region of conventional make.

Before making this invention the present applicant tentatively made a buffer region explicitly designed for reduction of the warping of wafers. That tentative buffer region was in the form of alternating two different kinds of layers, consisting of first buffer layers each having several sublayers and second buffer layers having no sublayers. The lattice constant of the non-sublayered second buffer layers was made closer to that of one of the sublayers of each multi-sublayered first buffer layer that contained a relatively high proportion of aluminum, than to that of the main semiconductor region grown on this tentative buffer region. The stresses exerted by the non-sublayered second buffer layers on the main semiconductor region were opposite in direction to those exerted by the multi-sublayered first buffer layers thereon. Although this prior buffer configuration was expected to lessen the warping of the wafers significantly, it actually proved incapable of alleviating the stresses without sacrificing the crystallinity of the main semiconductor region.

The problems to be solved by the instant invention have been discussed hereinbefore as limited to the silicon substrate wafers. It is to be noted, however, that the same problems occur with substrates that are made from materials other than silicon but that are nearly as different in linear expansion coefficient from the nitride semiconductor region as the silicon substrate is.

### SUMMARY OF THE INVENTION

The present invention has it as an object to reduce the warpage of the wafers for nitrides and other compound semiconductor devices to a minimum.

Another object of the invention is to improve the crystallinity of the main semiconductor region grown on a silicon or other substrate to provide matrices of desired semiconductor devices.

Briefly, the present invention concerns a wafer for fabrication of compound semiconductor devices, having a substrate, a buffer region formed on the substrate, and a main semiconductor region of compound semiconductors providing matrices of the semiconductor devices to be made. The invention particularly pertains to improvements in the configuration of the buffer region of the wafer. The improved buffer region comprises two or more alternations of first and second buffer layers. Each buffer layer has alternating first and second sublayers. The first sublayers of each first buffer layer are made from a nitride semiconductor containing a prescribed proportion of aluminum, and the second sublayers of each first buffer layer from a nitride semiconductor containing aluminum in a proportion that is either zero or less than the aluminum proportion of the first sublayers of the first buffer layers. The second buffer layers on the other hand are made from a nitride semiconductor containing aluminum in a proportion that is either zero or less than the aluminum proportion of the first sublayers of the first buffer layers. Each second buffer layer is thicker than each first or second sublayer of the first buffer layers and has a multiplicity of voids created therein.

Thus, in essence, the improved buffer region of this invention is comprised of alternating multi-sublayered first buffer layers and non-sublayered, open-worked second buffer layers. The two different kinds of buffer layers in combination attain the above stated objectives of wafer warpage reduction and the improvement of the crystallinity of the main semiconductor region formed thereon.

The invention also concerns a method of fabricating the wafer of the above summarized construction. All the constituent layers of the buffer region and the main semiconductor region thereon are successively formed by vapor-phase growth of nitride semiconductors on the substrate. Even the required voids in the second buffer layers are formed in the course of such vapor-phase growth of the successive layers, simply by, after the growth of each second buffer layer, introducing materials for the lowermost first sublayer of the next first buffer layer into the reactor at a rate low enough for the voids to be created by the etching action of the reactor atmosphere.

The above and other objects, features and advantages of this invention will become more apparent, and the invention itself will best be understood, from a study of the following description and appended claims, with reference had to the attached drawings showing some preferable embodiments of the invention.

### BRIEF DESCRIPTION OF THE DRAWINGS

FIG. 1 is a diagrammatic illustration of the wafer for fabrication of transistors according to the invention.

FIG. 2 is an enlarged, partial section through the buffer region of the wafer.

FIG. 3 is an enlargement of part of the buffer region of FIG. 2.

FIG. 4 is a diagrammatic illustration of one of the transistors made from the wafer of FIG. 1.

FIG. 5 is a view similar to FIG. 4 but showing an LED that can be made from the wafer according to the invention.

### DETAILED DESCRIPTION

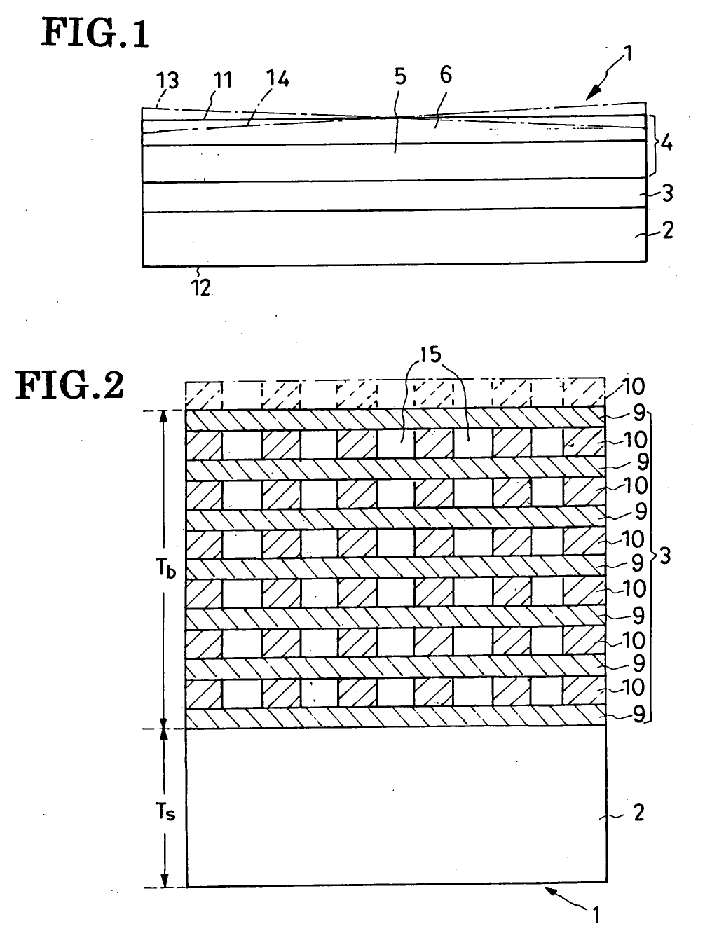

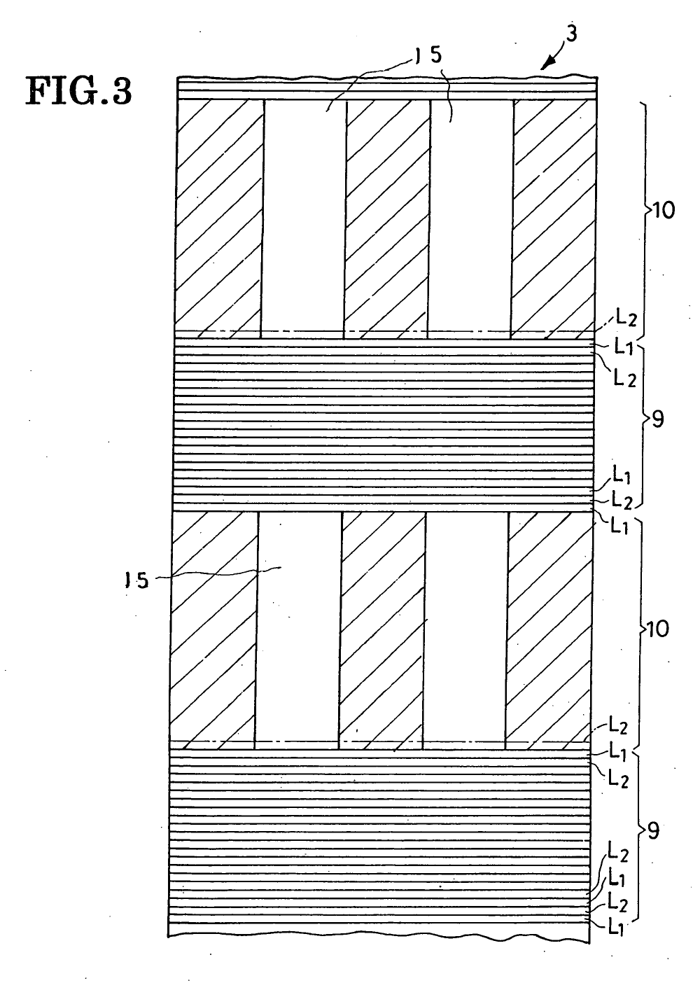

The present invention will now be described more specifically as applied to a wafer or base plate for fabrication of high-electron-mobility heterojunction FETs (hereinafter referred to simply as transistors). Such a wafer is drawn schematically in FIG. 1 and therein generally labeled 1. Broadly, the wafer 1 comprises a semiconducting silicon substrate 2, a buffer region 3 of nitride or other Groups III-V compound semiconductors, and a main semiconductor region 4 of nitride or other Groups III-V compound semiconductors for providing matrices of the transistors. Although shown as a single layer in FIG. 1 for simplicity, the buffer region 3 is in fact constituted of a plurality or multiplicity of alternating two different kinds of layers according to the novel concepts of this invention, as will be later detailed with reference to FIGS. 2 and 3.

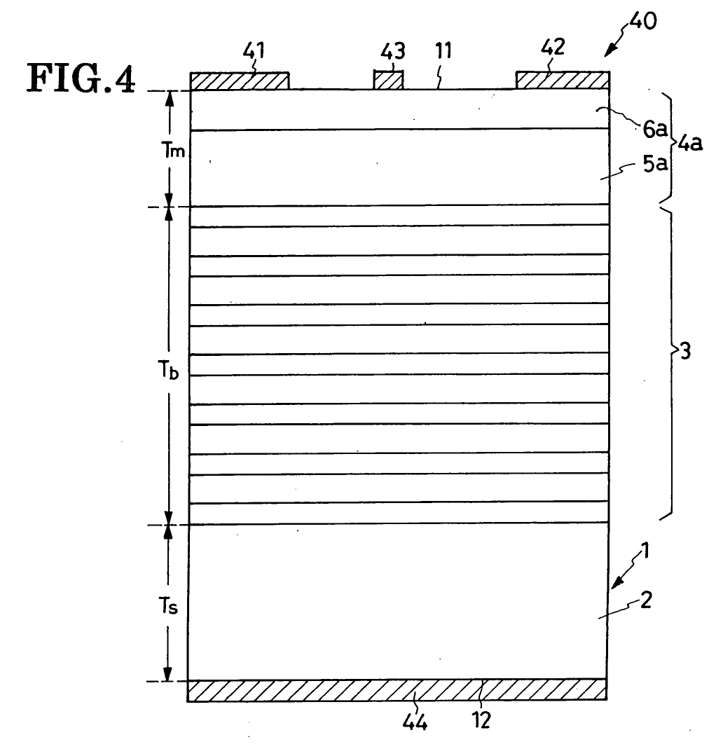

The main semiconductor region 4 is shown to have two semiconductor layers 5 and 6 of Groups III-V compound semiconductors for providing respectively the electron transit layer 5ₐ, FIG. 4, and electron supply layer 6ₐ of the transistors, one of which is shown completed in that figure. Directly overlying the buffer region 3, the first semiconductor layer 5 is made from any of the nitride semiconductors that are generally defined as:
AlₐM_{b}Ga_{1-a-b}N
where M is at least either of indium and boron; the subscript a is a numeral that is equal to or greater than zero and equal to or less than one; the subscript b is a numeral that is equal to or greater than zero and less than one; and the sum of a and b is equal to or less than one. Particularly preferred is undoped aluminum gallium nitride, AlGaN (the subscript b is zero in the formula above).

The second semiconductor layer 6 of the main semiconductor region 4 is made from any of the nitride semiconductors, plus an n-type impurity such as silicon, that are generally defined as:
AlₓGa₁₋ₓN
where the subscriptₓ is a numeral that is greater than zero and less than one. Silicon-doped Al_{0.2}Ga_{0.8}N is particularly preferred.

The silicon substrate 2 is of p-type monocrystalline silicon, containing boron or other Group III elements as a conductivity type determinant. The major surface of the silicon substrate 2 on which is formed the buffer region 3 is exactly (111) in terms of Miller indices. The impurity concentration of the silicon substrate 2 is in the range of 1×10¹³ through 1×10¹⁴ cm⁻³, and its resistivity in the range of 100 to 1000 ohm-centimeters. The silicon substrate 2 should have a thickness Tₛ of 300 to 1000 micrometers, which is greater than the total thickness of the buffer region 3 and main semiconductor region 4, in order to serve the additional purpose of mechanically supporting these regions 3 and 4. The silicon substrate 2 could be of n-type.

As depicted fragmentarily and on an enlarged scale in FIG. 2, the buffer region 3 is a lamination of alternating two different types of layers as aforesaid, that is, multi-sublayered first buffer layers 9 and non-sublayered, open-worked second buffer layers 10. These buffer layers 9 and 10 are successively grown by epitaxy on the silicon substrate 2. The buffer region 3 consists of six alternations of the first and second buffer layers 9 and 10, plus an additional first buffer layer at the top, in this particular embodiment of the invention. However, as indicated by the broken lines in FIG. 2, the buffer region 3 could be topped by the open-worked second buffer layer 10.

Speaking more broadly, the first buffer layers 9 may be from two to fifty in number, preferably from three to fifty, and most desirably from five to ten. The second buffer layers 10 may be from one to 49 in number, preferably from two to forty-nine, and most desirably from five to nine. Generally, the greater the numbers of pairs of first and second buffer layers 9 and 10, the better will they buffer the stresses due to the difference in linear expansion coefficient between the silicon substrate 2 and the nitride-based semiconductor region 4. The thickness T_{b} of the buffer region 3 may be from 70 to 3000 nanometers. The thickness of each first buffer layer 9 may be from 20 to 400 nanometers, preferably from 50 to 150 nanometers. The thickness of each second buffer layer 10 may be from 20 to 400 nanometers, preferably from 100 to 200 nanometers.

FIG. 3 is a still more enlarged, fragmentary representation of the buffer region 3. It is clear from this figure that each first buffer layer 9 is a lamination of alternating two different kinds of sublayers L₁ and L₂. Ten alternations of these sublayers L₁ and L₂ plus an additional first sublayer L₁ at the top are herein shown for each buffer layer 9 by way of example. Such an additional sublayer at the top is not a necessity; instead, each buffer layer 9 could be made up from even numbers of sublayers L₁ and L₂. In this latter case, as indicated in phantom outline in FIG. 3, each buffer layer 9 would be topped by the second sublayer L₂.

Generally speaking, the first sublayers L₁ of each buffer layer 9 may be from three to fifth in number, preferably from five to twenty. The second sublayers L₂ of each buffer layer 9 may be from two to forty-nine in number, preferably from four to nineteen.

The first sublayers L₁ of the first buffer layers 9 are all made from an aluminum-containing nitride semiconductor selected from among the Groups III-V compound semiconductors that are generally defined as:
AlₓM_{y}Ga_{1-x-y}N
where M is at least either of indium and boron; the subscript x is a numeral that is greater than zero and equal to or less than one; the subscript y is a numeral that is equal to or greater than zero and less than one; and the sum of x and y is equal to or less than one. Specific examples meeting this formula are aluminum nitride (AlN), aluminum indium nitride (AlInN), aluminum gallium nitride (AlGaN), and aluminum indium aluminum nitride (AlInGaN). AlN is currently recommended. The thickness of each first sublayer L₁ may be from 0.2 to 20 nanometers, preferably from one to seven nanometers, and most desirably from one to five nanometers. Made in this most desirable thickness range, the first sublayers L₁ will offer the quantum-mechanical tunnel effect.

The second sublayers L₂ of the first buffer layers 9 are all made from a nitride semiconductor that does not contain aluminum or that does contain aluminum in a proportion less than that of the first sublayers L₁. The possible materials for the second sublayers L₂ are the Groups III-V compound semiconductors that are generally expressed by the formula:
AlₐM_{b}Ga_{1-a-b}N
where M is at least either of indium and boron; the subscript a is a numeral that is equal to or greater than zero and less than one and, additionally, less than x in the formula above defining the materials for the first buffer sublayers L₁; the subscript b is also a numeral that is equal to or greater than zero and less than one; and the sum of a and b is equal to or less than one. Thus the second buffer sublayers L₂ can be made from such compounds as GaN, InGaN, AlInN, AlGaN, and AlInGaN, of which GaN is currently preferred. The thickness of each second sublayer L₂ may be from 0.2 to 30.0 nanometers, preferably from two to twenty nanometers, and most desirably from three to ten nanometers.

The open-worked second buffer layers 10 of the buffer region 3 are also made from a nitride semiconductor that does not contain aluminum or that does contain aluminum in a proportion less than that of the first sublayers L₁ of the first buffer layers 9. The possible materials for the second sublayers L₂ are the Groups III-V compound semiconductors that are generally expressed by the formula:
AlₐM_{b}Ga_{1-a-b}N
where M is at least either of indium and boron; the subscript a is a numeral that is equal to or greater than zero and equal to or less than one and, additionally, less than x in the formula above defining the materials for the first buffer sublayers L₁ of the first buffer layer 9; the subscript b is a numeral that is equal to or greater than zero and less than one; and the sum of a and b is equal to or less than one. Thus the second buffer layers 10 can also be made from such compounds as GaN, InGaN, AlInN, AlGaN, and AlInGaN, of which GaN is currently preferred. The thickness of each second buffer layer 10 may be from five to fifty, preferably from ten to forty, times the thickness of each second sublayer L₂ of the first buffer layers 9.

As indicated greatly simplified and idealized in both FIGS. 2 and 3, the second buffer layers 10 of the buffer region 3 each contain a multiplicity of interstices or voids 15 (hence the epithet “open-worked”). The voids 15 are dispersed throughout each second buffer layer 10 of the buffer region 3 in order to terminate dislocations extending from the neighboring layers, and in order to prevent warping of the wafer 1. In other words, the buffer region 3 has the voids 15 disposed along the direction extended in parallel to the major surface 11, and the voids 15 disposed along the direction which intersects perpendicularly with the major surface 11. As viewed normal to the major surface 11, FIG. 1, of the wafer 1, these voids 15 take the form of stripes of crisscross arrangement in this particular embodiment, leaving a more or less regular array of islandlike portions indicated by hatching in FIGS. 2 and 3. Alternatively, each second buffer layer 10 may be lattice shaped, having a more or less regular array of discrete voids defined therein.

The idealized showing in FIGS. 2 and 3 of the voids 15 as being identical in shape and regular in arrangement is for the ease of understanding only. In practice the voids 15 may differ in shape and be irregular in arrangement. It is also unnecessary that the voids extend throughout the thickness of each second buffer layer 10.

Still further, despite the showing of FIGS. 2 and 3, the surfaces defining the voids 15 in the second buffer layers 10 may not necessarily extend normal to the opposite major surfaces of each such layer. Thus, for instance, each second buffer layer 10 may have an array of pyramid-shaped columns defined by a latticework of grooves each having a plurality of lateral surfaces that diverge apart as they extend from the silicon substrate 2 toward the main semiconductor region 4. As another example, each second buffer layer 10 may have an array of reverse pyramid voids or conical voids.

The aforesaid pyramidal columns with the latticework of grooves of divergent cross section, in particular, have proved to serve most efficaciously the purpose of cutting short the transfer of dislocations. A possible explanation for this will be that upon extension of dislocations into each second buffer layer 10 from the underlying first buffer layer 9, the slanting walls of the voids 15 deflect and terminate such dislocations. Thus is the dislocation density of the main semiconductor region 4 particularly well reduced.

Despite the showing of FIGS. 2 and 3, the voids 15 in the second buffer layers 10 need not be bottomed against the first buffer layers 9. The voids 15 may instead differ in depth, some reaching the first buffer layers 9 and others terminating short of them at various distances therefrom.

It is unnecessary, either, that the voids 15 be of constant width as in FIGS. 2 and 3; instead, they may differ in width from one void to another, or from one part to another of a single continuous void. The voids 15 in each second buffer layer 10 should not, however, be so wide as to prevent the creation of a more or less planar first buffer layer 9 thereon. From these considerations it is recommended that the voids 15 be each made from one to 5000 nanometers in width and, in depth, equal to or less than the depth of each second layer 10.

### Method of Fabrication

The fabrication of the semiconductor wafer 1, configured as above described with reference to FIGS. 1-3, starts with the preparation of the silicon substrate 2. For making the lowermost multi-sublayered first buffer layer 9 on this substrate 2, the first and second sublayers L₁ and L₂ may be alternately grown a prescribed number of times by the known method of metal organic vapor phase epitaxy (MOVPE). If the first sublayers L₁ are to be made from AlN, trimethyl aluminum (TMA) and ammonia (NH₃) may be charged in required proportions into the MOVPE reactor until an AlN layer is grown each time to a thickness of five nanometers or so. If the second sublayers L₂ are to be made from GaN, then trimethyl gallium (TMG) and NH₃ may be charged in required proportions into the reactor until a GaN layer is grown each time to a thickness of five nanometers or so.

The lowermost non-sublayered, open-worked second buffer layer 10 is created upon completion of the lowermost multi-sublayered first buffer layer 9. The same material as that of the second sublayers L₂ of the first buffer layer 9 may be grown in the same MOVPE reactor for creation of the second buffer layer 10. However, the second buffer layers 10 may be made from a different material, such as InGaN, from that of the second sublayers L₂ of the first buffer layer 9. The lowermost second buffer layer 10 thus grown on the lowermost first buffer layer 9 is not yet open-worked but is to be in the course of the ensuing fabrication of the lowest first sublayer L₁ of the second lowest multi-sublayered first buffer layer 9.

Then comes the fabrication of that lowest first sublayer L₁ of the second lowest multi-sublayered first buffer layer 9 following the creation of the not-yet-open-worked lowermost second buffer layer 10. The lowest first sublayer L₁ of the second lowest first buffer layer 9 is grown on the not-yet-open-worked lowermost second buffer layer 10 by introducing TMA into the reactor at a reduced rate. As the lowest first sublayer L₁ is thus grown at a reduced rate, there will be an initial phase of such growth in which AlN will crystallize sporadically, rather than uniformly, over the surface of the GaN second buffer layer 10. Those parts of the surface of the second buffer layer 10 which are left exposed by the sparse deposition of AlN will then be subjected to the etching action of the reactor atmosphere, with the consequent creation of the voids 15 in the second buffer layer.

For example, if AlN crystallizes in discrete islandlike regions, arranged more or less in columns and rows, on the surface of the second buffer layer 10, then the voids 15 will appear more or less in latticework. The open-worked second buffer layer 10 will then be constituted of a multiplicity of islandlike regions. If AlN crystallizes more or less in continuous, latticelike arrangement, on the other hand, then the voids 15 will be etched in the discrete parts of the surface of the second buffer layer 10 which are left uncovered by the latticed AlN deposit. The open-worked second buffer layer 10 will then be lattice-shaped.

Now has been formed the lowermost first sublayer L₁ of the second lowest first buffer layer 9, with the concurrent creation of the voids 15 in the lowermost second buffer layer 10. The fabrication of the second lowest first buffer layer 9 may be continued by repeatedly and alternately creating the second buffer sublayers L₂ and first buffer sublayers L₁ by the same method as in the creation of the lowermost first buffer layer 9 explained above. The formation of the buffer region 3 comes to an end as the required number of pairs of the first and second buffer layers 9 and 10 are fabricated by the same method as the above-described lowermost pair of first and second buffer layers.

Next comes the growth of the main semiconductor region 4, FIG. 1, on the multi-layered buffer region 3. The first semiconductor layer 5 of this region 4 may be formed by growing undoped AlGaN on the buffer region 3 by MOVPE, and the second semiconductor layer 6 may be formed likewise.

Then the wafer 1 is electroded for providing the transistors each constructed as in FIG. 4 and therein generally designated 40. A source electrode 41, drain electrode 42 and gate electrode 43 are conventionally formed on the first major surface 11 of the wafer for each transistor 40. A back electrode 44 is formed on the other major surface 12 of the wafer. Then the wafer is diced into the individual transistors 40.

The advantages gained by this particular wafer 1 may now be briefly studied. Constituted of alternating multi-sublayered first buffer layers 9 and open-worked, non-sublayered second buffer layers 10, the buffer region 3 according to the invention can better keep the wafer 1 from warping then heretofore. Generally, a wafer incorporating a conventional buffer region tends to warp as indicated by the broken line 13 in FIG. 1 if the substrate is higher in lattice constant than the buffer region. If the substrate is less in lattice constant then the buffer region, on the other hand, then the wafer will warp as indicated by the broken line 14. The present invention precludes such warping of the wafer in either direction by virtue of the alternate arrangement of the first and second buffer layers 9 and 10.

The open-worked second buffer layers 10 in particular have a lattice constant that is closer to that of the main semiconductor region 4, particularly to that of the electron transit layer 5ₐ, than to that of the first sublayers L₁ of the first buffer layers 9. Consequently, the second buffer layers 10 tend to stress the main semiconductor region 4 in a direction opposite to that in which the first buffer layers 9 do. Thus the alternating first and second buffer layers 9 and 10 counteract each other to mitigate the transfer of stresses to the main semiconductor region 4. The stresses are particularly well dispersed by reason of the voids 15 in the second buffer layers 10.

It is a well known fact that that wafers must be as far free from warpage as possible (e.g., less than 40 micrometers in the case of a five-inch-diameter wafer) for execution of photolithographic and other manufacturing processes thereon as required. The wafers of this invention, fabricated by the method set forth above, with a five-inch diameter and having the main semiconductor region 4 formed to a thickness of 1.2 to 2.0 micrometers, had a warpage averaging fourteen micrometers in the direction indicated by the broken line 14 in FIG. 1. For comparison, prior art wafers were made which had a buffer region consisting of forty alternations of five-nanometer-thick AlN layers and twenty-nanometer-thick GaN layers. These prior art wafers had an average warpage of one hundred micrometers in the direction indicated by the broken line 13 in FIG. 1.

Additional advantages are as follows:

1. The open-worked second layers 10 of the buffer region 3 effectively terminate the dislocations that have occurred in the first layers 9 of the buffer region, with a consequent decrease in the dislocation density of the main semiconductor region 4. The dislocation density at the first major surface 11 of the main semiconductor region 4 was 5×10⁸ cm⁻², compared to that of 2×10¹⁰ cm⁻² according to the noted prior art with the buffer region of AlN and GaN layers.

2. The surface roughness δ rms of the wafer 1 was less than 0.2 nanometer, a drastic improvement over that of 0.48 nanometer according to the same prior art.

3. Electron mobility at the electron transit layer 6ₐ of the transistor 40 was 1600 cm²/Vs, much higher than 1200 cm²/Vs according to the same prior art.

4. The transistor 40, or any other semiconductor device made according to the invention, has proved to withstand a voltage of as high as 600 volts or more by making the thickness Tₘ of the main semiconductor region 4 not less than 1.2 micrometers.

5. The current leakage of the semiconductor device is reducible by making the main semiconductor region 4 as thick as 1.2 micrometers or more.

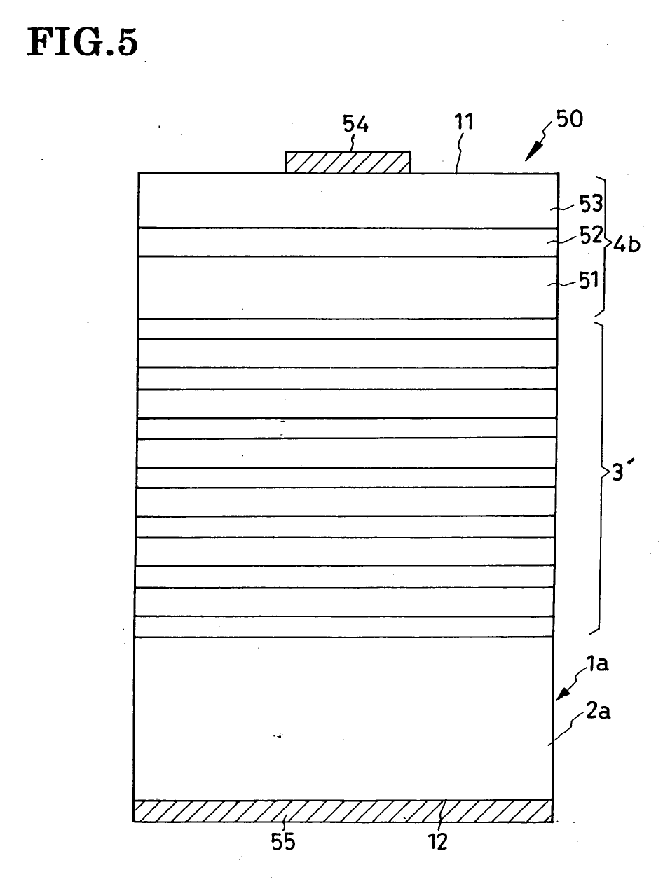

### Embodiment of FIG. 5

In FIG. 5 is the invention shown embodied in an LED 50 made from a semiconductor base plate or wafer 1ₐ. This wafer 1ₐ comprises a silicon substrate 2ₐ and, successively grown thereon by epitaxy, a buffer region 3′ and main semiconductor region 4_{b}. The buffer region 3′ is doped into n-type conductivity but is otherwise of the same construction as the buffer region 3 of the previous embodiment.

The silicon substrate 2ₐ differs from its FIG. 4 counterpart 2 only in impurity concentration and resistivity. The silicon substrate 2ₐ has an impurity concentration ranging from 5×10¹⁸ cm⁻³ to 5×10¹⁹ cm⁻³, and a resistivity ranging from 0.0001 to 0.0100 ohm-centimeter. The silicon substrate 2ₐ is therefore electroconductive, providing a current path between anode 54 and cathode 55. The silicon substrate 2ₐ is as thick as from 300 to 1000 micrometers in order to mechanically support the buffer region 3 and main semiconductor region 4_{b}.

Although the n-type buffer region 3′ is shown to be in direct contact with the p-type silicon substrate 2ₐ, a voltage drop across the boundary between these regions is negligible when a forward bias voltage is impressed between anode 54 and cathode 55. This is because, first of all, the substrate 2ₐ and buffer region 3′ are in heterojunction and secondly because a layer of an alloy, not shown, is invariably created between them. Alternatively, the silicon substrate 2ₐ could be of n-type and be overlaid with the n-type buffer region 3′.

The main semiconductor region 4_{b} comprises an n-type nitride semiconductor layer or lower cladding 51, an active layer 52, and a p-type nitride semiconductor region or upper cladding 53. These three layers constitute in combination the light-generating part of the LED 50. A more detailed description of the compositions of these light-generating layers 51-53 follows.

Grown epitaxially on the buffer region 3′, the n-type nitride semiconductor layer 51 is made by adding an n-type dopant to any of the nitride semiconductors that are generally defined by the formula:
AlₓIn_{y}Ga_{1-x-y}N
where the subscripts x and y are both numerals that are equal to or greater than zero and less than one. Particularly preferred is n-type GaN (both x and y are zero in the formula above).

The active layer 52 is made from any of the undoped nitride semiconductors that are generally defined as:
AlₓIn_{y}Ga_{1-x-y}N
where the subscripts x and y are both numerals that are equal to or greater than zero and less than one. Particularly preferred is InGaN (x is zero in the formula above). The active layer 52 may be of a single layer as shown or, preferably, of the known multiple quantum well configuration. Also, this layer 52 may be doped with a conductivity type determinant. It may be mentioned that the LED will generate light even without the active layer 52.

The p-type nitride semiconductor layer 53 is made by adding a p-type dopant to any of the nitride semiconductors that are generally defined as:
AlₓIn_{y}Ga_{1-x-y}N
where the subscripts x and y are both numerals that are equal to or greater than zero and less than one. Particularly preferred is p-type GaN (both x and y are zero in the formula above).

Made up of the three layers 51-53 of the foregoing compositions, the main semiconductor region 4_{b} is grown on the silicon substrate 2ₐ via the buffer region 3′. The main semiconductor region 4_{b} of the LED 50 is therefore just as favorable in crystallinity and flatness as the main semiconductor region 4ₐ, FIG. 4, of the transistor 40.

As shown also in FIG. 5, the LED 50 has an anode 54 formed centrally on the first major surface 11 of the wafer 1ₐ in electric contact with the p-type cladding 53 of the main semiconductor region 4_{b}, and a cathode 55 formed on the underside of the silicon substrate 2ₐ. The anode 54 could be formed on the p-type cladding 53 via a contact layer of a p-type nitride semiconductor. The cathode 55 could be connected to the buffer region 3 or to the n-type nitride semiconductor layer 5 1.

Incorporating the multilayered buffer region 3′ similar to its FIGS. 1-4 counterpart 3, the LED 50 gains the same advantages as the transistor 1. An additional advantage is the less voltage requirement of the LED thanks to the high conductivity of the silicon substrate 2ₐ.

### Possible Modifications

Although the semiconductor wafer with the multilayered buffer region according to the present invention has been shown and described hereinbefore in terms of but two currently preferred forms, it is understood that the invention may be embodied in a variety of other forms within the usual knowledge of the semiconductor specialists. The following is a brief list of possible modifications, alterations and adaptations of the illustrated embodiments which are all believed to fall within the scope of the invention:

1. The invention is applicable to the fabrication of various semiconductor devices other than the exemplified heterojunction HEMTs and LEDs, such as bipolar transistors, insulated-gate field-effect transistors, rectifier diodes, and metal-semiconductor field-effect transistors.

2. The substrate can be made from materials other than silicon adoptable as long as they permit epitaxial growth of nitride semiconductors, examples being sapphire, silicon compound, zinc oxide, neodymium gallium oxide, and gallium arsenide.

3. The buffer region 3 or 3′ could be constituted of arbitrary numbers of first layers 9 and second layers 10. Normally, the number of the first layers 9 may be from two to fifth, and that of the second layers 10 from one to forty-nine.

4. The numbers of the sublayers L₁ and L₂ of each first buffer layer 9 are also variable as required or desired. Normally, the number of the first sublayers L₁ of each first buffer layer may be from two to fifty, and that of the second sublayers L₂ from one to forty-nine.

5. The multi-sublayered first layers 9 of the buffer region 3 or 3′ need not be all of the same make. For example, the second sublayers L₂ of the first layers 9 may be made progressively thicker or thinner as they come closer to the main semiconductor region 4ₐ or 4_{b}. Or the numbers of the sublayers L₁ and L₂ in each first layer 9 may be made progressively more or less as it comes closer to the main semiconductor region 4ₐ or 4_{b}.

6. The open-worked second layers 10 of the buffer region 3 or 3′ need not be all of the same make, either. For example, they may be made progressively thicker or thinner as they come closer to the main semiconductor region 4ₐ or 4_{b}.

7. The voids 15 in the second buffer layers 10 of the buffer region 3 or 3′ may be created by masking and etching.

8. The wafer suggested by the instant invention may be made by various known methods besides the method proposed herein. One such known method is use of the so-called off-angled substrate having the step-like surface, on which the multi-sublayered first buffer layers 9 may be grown in fractional superlattice configuration. This method is called step-flow method.

9. All or some constituent layers of the buffer region 3 may be doped with, for example, an n-type impurity.

What is claimed is:

1. A wafer for fabrication of semiconductor devices, having a substrate, a buffer region formed on the substrate, and a main semiconductor region of compound semiconductors providing matrices of the semiconductor devices to be made, the buffer region of the wafer comprising:
(a) a plurality of first buffer layers each having alternating first and second sublayers, the first sublayers of the first buffer layers being made from a nitride semiconductor containing a prescribed proportion of aluminum, the second sublayers of the first buffer layers being made from a nitride semiconductor containing aluminum in a proportion that is either zero or less than the aluminum proportion of the first sublayers of the first buffer layers; and
(b) a plurality of second buffer layers arranged alternately with the first buffer layers, the second buffer layers being made from a nitride semiconductor containing aluminum in a proportion that is either zero or less than the aluminum proportion of the first sublayers of the first buffer layers, each second buffer layer being thicker than each first or second sublayer of the first buffer layers and having a multiplicity of voids created therein.

2. The wafer as recited in claim 1, wherein the first buffer layers of the buffer region are greater in number than the second buffer layers thereof by one.

3. The wafer as recited in claim 2, wherein the first sublayers of each first buffer layer of the buffer region are greater in number than the second sublayers of each first buffer layer of the buffer region by one.

4. The wafer as recited in claim 3, wherein the first sublayers of each first buffer layer of the buffer region are from three to fifth in number, and wherein the second sublayers of each first buffer layer of the buffer region are from two to forty-nine in number.

5. The wafer as recited in claim 1, wherein the substrate is of silicon;
wherein the first sublayers of the first buffer layers of the buffer region are made from any of nitride semiconductors that are generally defined by the formula:
AlₓM_{y}Ga_{1-x-y}N
where M is at least either of indium and boron; the subscript x is a numeral that is greater than zero and equal to or less than one; the subscript y is a numeral that is equal to or greater than zero and less than one; and the sum of x and y is equal to or less than one;
wherein the second sublayers of the first buffer layers of the buffer region are made from any of nitride semiconductors that are generally defined by the formula:
AlₐM_{b}Ga_{1-a-b}N
where M is at least either of indium and boron; the subscript a is a numeral that is equal to or greater than zero and less than one and, additionally, less than x in the formula above defining the materials for the first sublayers of first buffer layers of the buffer region; the subscript b is also a numeral that is equal to or greater than zero and less than one; and the sum of a and b is equal to or less than one; and
wherein the second buffer layers of the buffer region are made from any of nitride semiconductors that are generally defined by the formula:
AlₐM_{b}Ga_{1-a-b}N
where M is at least either of indium and boron; the subscript a is a numeral that is equal to or greater than zero and less than one and, additionally, less than x in the formula above defining the materials for the first sublayers of first buffer layers of the buffer region; the subscript b is also a numeral that is equal to or greater than zero and less than one; and the sum of a and b is equal to or less than one.

6. The wafer as recited in claim 1, wherein the first and the second layers of the buffer region are both each from about 20 to about 400 nanometers in thickness.

7. The wafer as recited in claim 1, wherein the first sublayers of the first buffer layers of the buffer region are each from about 0.2 to about 20.0 nanometers in thickness, and wherein the second sublayers of the first buffer layers of the buffer region are each from 0.2 to about 30.0 nanometers in thickness.

8. The wafer as recited in claim 1, wherein the voids are dispersed throughout each second buffer layer of the buffer region.

9. A method of fabricating semiconductor devices in the form of a wafer, which comprises:
(a) growing a multi-sublayered first buffer layer on a substrate in a vapor phase, the first buffer layer having a prescribed number of alternations of first and second sublayers, the first sublayers of the first buffer layer being made from a nitride semiconductor containing a prescribed proportion of aluminum, the second sublayers of the first buffer layer being made from a nitride semiconductor containing aluminum in a proportion that is either zero or less than the aluminum proportion of the first sublayers of the first buffer layer;
(b) growing an open-worked second buffer layer on the first buffer layer in a vapor phase to a thickness greater than that of each first or second sublayer of the first buffer layer, the second buffer layer being made from a nitride semiconductor containing aluminum in a proportion that is either zero or less than the aluminum proportion of the first sublayers of the first buffer layer;
(c) repeating the vapor-phase growth of the first and the second buffer layers a prescribed number of times to provide a multilayered buffer region; and
(d) growing a main semiconductor region of compound semiconductors on the buffer region in a vapor phase, the main semiconductor region containing matrices of the semiconductor devices to be made.

10. A method of fabricating semiconductor devices in the form of a wafer, which comprises:
(a) growing a first sublayer of a first buffer layer on a substrate in a vapor phase within a reactor, the first sublayer being made from a nitride semiconductor containing a prescribed proportion of aluminum;
(b) growing a second sublayer of the multi-sublayered first buffer layer on the first sublayer in a vapor phase within the reactor, the second sublayer being made from a nitride semiconductor containing aluminum in a proportion that is either zero or less than the aluminum proportion of the first sublayer of the first buffer layer;
(c) repeating the vapor-phase growth of the first and the second sublayer of the first buffer layer a prescribed number of times to provide one multi-sublayered first buffer layer;
(d) growing an open-worked second buffer layer on the first buffer layer in a vapor phase within the reactor to a thickness greater than that of each first or second sublayer of the first buffer layer, the second buffer layer being made from a nitride semiconductor containing aluminum in a proportion that is either zero or less than the aluminum proportion of the first sublayers of the first buffer layer;
(e) repeating the vapor-phase growth of the first and the second buffer layers a prescribed number of times to provide a multilayered buffer region; and
(f) growing a main semiconductor region of compound semiconductors on the buffer region in a vapor phase, the main semiconductor region containing matrices of the semiconductor devices to be made.

11. The method as recited in claim 10, wherein each open-worked second buffer layer of the multilayered buffer region has voids created therein by, following the growth of each second buffer layer, introducing materials for the first sublayer of the next first buffer layer at a reduced rate into the reactor.
